(19) United States
(12) Patent Application Publication
(10) Pub. No.: US 2026/0023640 A1
(43) Pub. Date: Jan. 22, 2026

(54) DATA DECOMPRESSION TECHNOLOGIES

(71) Applicant: Intel Corporation, Santa Clara, CA (US)

(72) Inventors: Fei Z. WANG, Shannon (IE); Laurent COQUEREL, Limerick (IE); Giovanni CABIDDU, Shannon (IE); John J. BROWNE, Limerick (IE)

(21) Appl. No.: 19/341,978

(22) Filed: Sep. 26, 2025

(51) Int. Cl. G06F 11/07; H03M 7/30

(52) U.S. Cl. CPC G06F 11/079; G06F 11/073; H03M 7/6041

(57) ABSTRACT

Examples described herein relate to an accelerator configured to: perform offloaded decompression of multiple frames of data based on a data compression format, wherein the perform offloaded decompression of the multiple frames of data comprises: based on failure to decompress a frame of the multiple frames of the data: indicate, to a requester, device data identifying at least one of: a successfully decompressed frame of the multiple frames of data or an unsuccessfully decompressed frame.

A processor can offload cryptographic, compression, or decompression tasks to accelerator devices to reduce computational loads on the processor. To perform data compression to reduce a size of data, an accelerator device replaces patterns or sequences of data with shorter representations. Dictionaries store patterns or sequences of data and corresponding shorter representations or code. To perform data decompression, the accelerator device scans for sequences that match entries in the dictionary and when a match is found, the accelerator outputs the corresponding data sequence instead of a code.

### BRIEF DESCRIPTION OF THE DRAWINGS

FIG. 1 depicts an example system.

FIG. 2 depicts an example of operations.

FIG. 3 depicts an example sequence.

FIG. 4 depicts an example of state generation from decompressing multiple frames sequentially.

FIG. 5 shows an examples of frame formats.

FIG. 6 depicts an example process.

FIG. 7 depicts an example accelerator.

FIG. 8 depicts an example system.

### DETAILED DESCRIPTION

A decompressor can receive a request to decompress multiple frames of data sequentially based on an applicable data compression standard. For example, for the Zstandard compression standard, a frame can include a header with a value that identifies the compression standard, compressed data split across one or more blocks, and a footer. If the decompressor processes a frame and generates decompressed data without error, the decompressor can continue decompressing compressed data of a next frame. The decompressor maintains a length of decompressed data and produced checksums on the decompressed data. However, if the decompressor operates in an all-or-nothing basis and the decompressor fails to decompress a frame, the decompressor produces no decompressed data. To decompress the multiple frames of data, the request is resubmitted and the decompression job commences from the start. If the decompressor is capable to decompress compressed data partially, the decompressor can stop on the section where the error occurred and previously decompressed data can be considered as valid.

Various examples of a decompressor can receive a request to decompress multiple frames of data and based on failure to decompress one of the multiple frames of data, indicate a state of a last decompressed frame or a first frame that failed to successfully decompress. The state can include Last Known Good State and can include, but is not limited to, valid data length (IBC) of compressed data that successfully decompressed up to the last decompressed frame, length of produced decompressed data (OBC) up to the number of bytes produced by the last good frame, and one or more checksum values calculated on successfully decompressed data of length IBC from a source buffer and/or successfully decompressed data of length OBC from a destination buffer.

Based on failure to decompress one of the multiple frames of data, the process can submit a request to a decompress one or more frames of data, which includes the frame that failed to successfully decompress. Decompression throughput can be improved by resuming decompression at a frame that failed to decompress instead of decompressing frames that were successfully decompressed. A design of a process can be simplified to avoid having to develop operations to parse frame information to extract the length of uncompressed data to determine what data was not successfully decompressed.

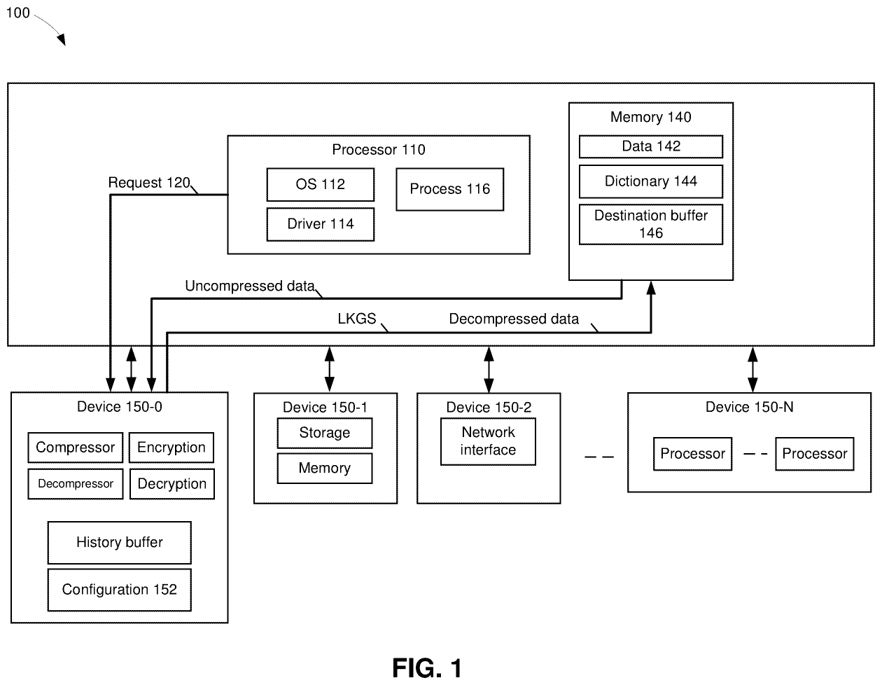

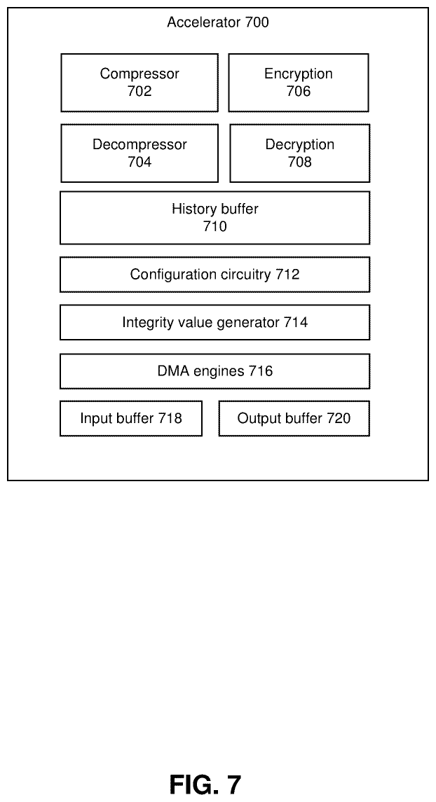

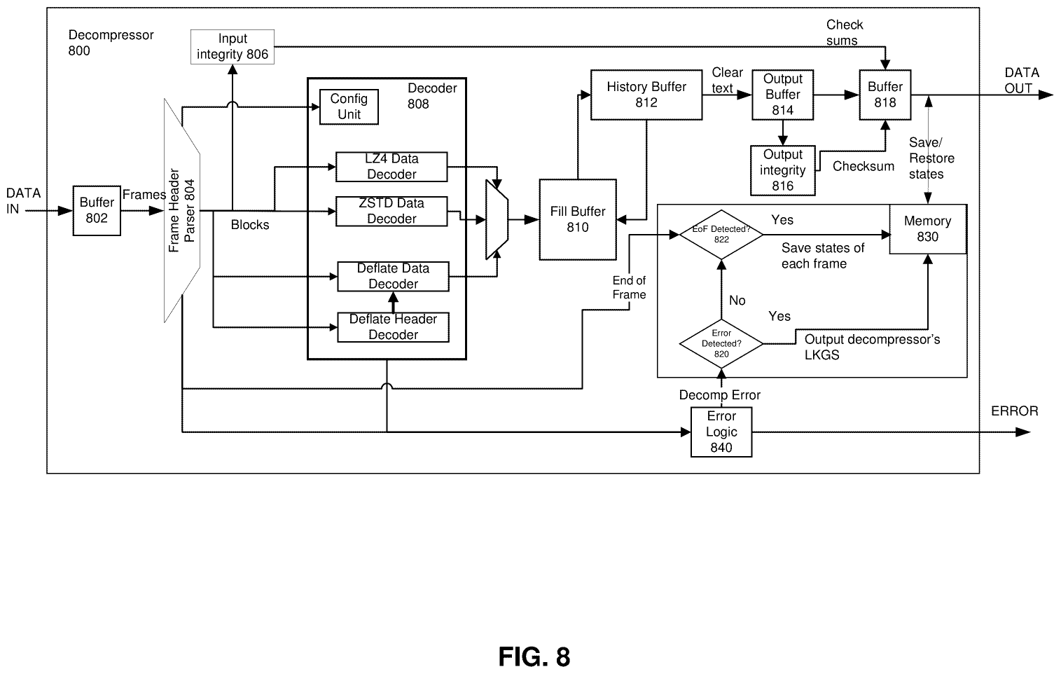

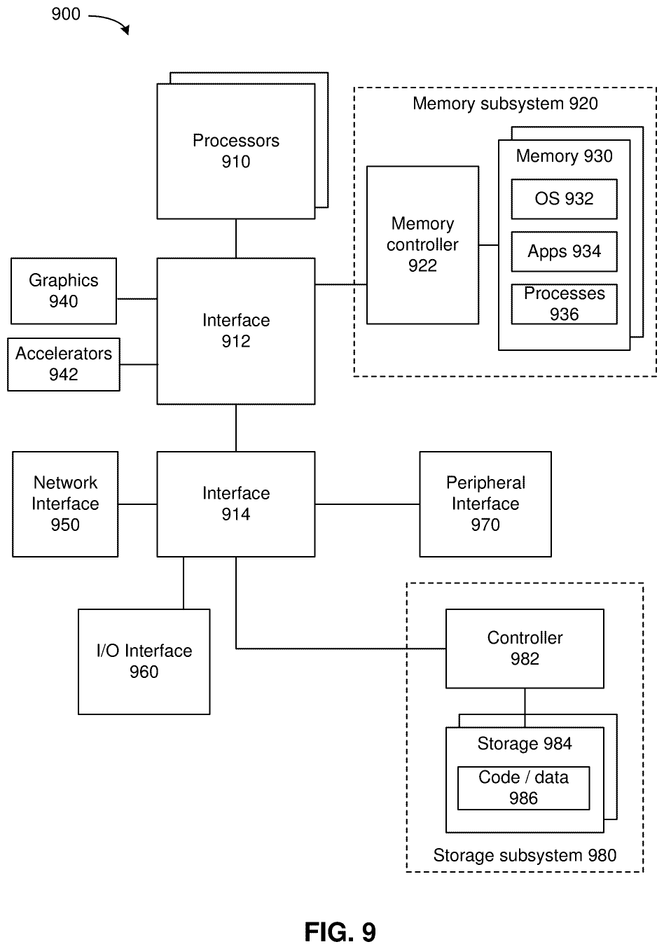

FIG. 1 depicts an example system. System 100 can include processor 110, memory 130, one or more of devices 150-0 to 150-N, where N is an integer, and other circuitry and software described at least with respect to FIGS. 7, 8, and/or 9. In some examples, system 100 can be implemented in a semiconductor package. The semiconductor package can include metal, plastic, glass, and/or ceramic casing that covers and encapsulates one or more semiconductor devices or integrated circuits (e.g., processor 110, memory 140, or one or more of devices 150-0 to 150-N) and provides communications within or among the one or more semiconductor devices or integrated circuits.

Processor 110 can include one or more general purpose processors, including at least: a central processing unit (CPU), a processor core, graphics processing unit (GPU), neural processing unit (NPU), general purpose GPU (GPGPU), field programmable gate array (FPGA), application specific integrated circuit (ASIC), tensor processing unit (TPU), matrix math unit (MMU), or other circuitry. A processor core can include an execution core or computational engine that is capable of executing instructions. A core can access to its own cache and read only memory (ROM), or multiple cores can share a cache or ROM. Accelerator cores, slices, and/or cores can be homogeneous (e.g., same processing capabilities) and/or heterogeneous devices (e.g., different processing capabilities). A core can be sold or designed by Intel®, ARM®, Advanced Micro Devices, Inc. (AMD)®, Qualcomm®, IBM®, Nvidia®, Broadcom®, Texas Instruments®, or compatible with reduced instruction set computer (RISC) instruction set architecture (ISA) (e.g., RISC-V), among others.

In some examples, processor-executed operating system (OS) 112 or driver 114 can advertise capability of one or more of devices 150-0 to 150-N to decompress data of multiple frames and based on failure to decompress a frame of the multiple frames, indicate state of the last successfully decompressed frame or first unsuccessfully decompressed frame at least to process 116. For example, OS 112 can call an application programming interface (API) or issue a configuration to configure one or more of devices 150-0 to 150-N to decompress data of multiple frames and based on failure to decompress a frame of the multiple frames, indicate state of the last successfully decompressed frame or first unsuccessfully decompressed frame to process 116.

Processor 110 can execute processes 116 that can request packet processing, packet transmission, data compression, data decompression, data encryption, data decryption, data copying, or other operations to be performed by one or more of devices 150-0 to 150-N. Processes 116 can include one or more of: an application, process, thread, a virtual machine (VM), micro VM, container, microservice, virtual function (VF), virtual device, or other virtualized execution environment.

One or more of devices 150-0 to 150-N can perform operations offloaded from processor 110. Devices 150-0 to 150-N can include one or more of: an accelerator, a memory device, a memory controller, a storage device, a storage controller, a network interface device, or other circuitry, such as circuitry described with respect to FIGS. 7, 8, and/or 9. A network interface device can include one or more of: a network interface controller (NIC), a remote direct memory access (RDMA)-enabled NIC, SmartNIC, router, switch, forwarding element, infrastructure in processing unit (IPU), data processing unit (DPU), edge processing unit (EPU), or Amazon Web Services (AWS) Nitro Card. An edge processing unit (EPU) can include a network interface device that utilizes processors and accelerators (e.g., digital signal processors (DSPs), signal processors, or wireless specific accelerators for Virtualized radio access networks (vRANs), cryptographic operations, compression/decompression, and so forth). A Nitro Card can include various circuitry to perform compression, decompression, encryption, or decryption operations as well as circuitry to perform input/output (I/O) operations.

One or more of devices 150-0 to 150-N can perform data compression, decompression, encryption, or decryption operations. In some cases, lossless or lossy compression and decompression schemes can be performed. Various compression and decompression schemes are available to be performed such as but not limited to Lempel Ziv (LZ) family of compression schemes including LZ77, LZ78, LZA, Zstandard (ZSTD), DEFLATE, GZIP, XP10, and Snappy standards and derivatives, among others.

In some examples, process 116 can issue request 120 to one or more of devices 150-0 to 150-N to decompress data and generate decompressed data. In some examples, process 116 can issue request 120 to cause decompression of multiple frames, a single frame, and/or a partial frame. For example, data to be decompressed can include multiple frames with a last frame being a partial frame, or the input data can be fixed length, such as, 256 KB, 1 MB, or other lengths. Request 120 can specify one or more of: operation to perform (e.g., compress data or decompress data), starting address of multiple frames of data 142 to decompress, length of data 142 that was successfully decompressed (e.g., Input Byte Count), starting address of allocated destination buffer size 146 to store decompressed data, valid previously decompressed data length (e.g., Output Byte Count), or other parameters.

In some examples, one or more of devices 150-0 to 150-N can decompress data 142 based on request 120. The decompressor device of the one or more of devices 150-0 to 150-N that performs data decompression can save a state while decompressing data based on decompressing a frame without an error and based on successful data decompression of a subsequent frame, overwrite a previous frame's state as a Last Known Good State. When multiple frames, requested to be decompressed, are decompressed without error, the decompressor provides the saved internal state to the device driver and process 116. However, in case of a failure to decompress a frame in the group of multiple frames, the decompressor can return a Last Known Good State to the device driver and an error code to indicate error occurred during multiple frames decompression operation to process 116. Decompressor internal state can include but are not limited to: input byte count (IBC) (e.g., size of input compressed data from a source buffer and that was successfully decompressed), output byte count (OBC) (e.g., size of successfully decompressed data (e.g., cleartext) and stored in a destination buffer), relative checksum or Cyclic Redundancy Check (CRC) up to the last successfully decompressed frame of length IBC in the source buffer, and relative checksum or CRC up to the last decompressed frame of length OBC in the destination buffer, and compression algorithm specific checksums (e.g., CRC32, Alder32, XXHash32, XXHash64, or others) of IBC and OBC.

Based on a receipt of an error code and the state, process 116 can utilize an error handler to determine a start address of a next frame (e.g., source buffer start address of data 142+IBC) and valid output data up to last known good state (e.g., destination buffer start address of destination buffer 146+OBC) and process 116 can resubmit a request to decompress a frame that was previously not successfully decompressed and zero or more other frames to decompress. An error handler may not parse decompressed frames to determine lengths of successfully decompressed frames. Process 116 can modify a size of the destination buffer to be sized to store the decompressed data.

One or more of devices 150-0 to 150-N can include Intel® QuickAssist Technology (Intel® QAT). An example QAT is described at least with respect to FIG. 7. One or more of devices 150-0 to 150-N can include accelerator cores, which can be organized into slices. A slice can include a logical partition of accelerator core and a slice can be configured to handle specific types of workloads, such as cryptographic operations (e.g., encryption, decryption) or data compression. QAT can perform offloaded compression and decompression of data by applying one of multiple different compression formats (e.g., Zstandard, DEFLATE, or others).

Processor 110 can access one or more of devices 150-0 to 150-N by die-to-die communications; chipset-to-chipset communications; circuit board-to-circuit board communications; package-to-package communications; and/or server-to-server communications. Die-to-die communications can utilize Embedded Multi-Die Interconnect Bridge (EMIB) or an interposer. Components of FIG. 1 (e.g., processor 110, memory 140, devices 150-0 to 150-N, or others) can be enclosed in one or more semiconductor packages. A semiconductor package can include metal, plastic, glass, and/or ceramic casing that encompass and provide communications within or among one or more semiconductor devices or integrated circuits.

In some examples, system 100 can be implemented as part of a system-on-a-chip (SoC) or system in package (SiP). Various examples of system 100 can be implemented as a discrete device, in a die, in a chip, on a die or chip mounted to a circuit board, in a package, or between multiple packages, in a server, in a CPU socket, or among multiple servers.

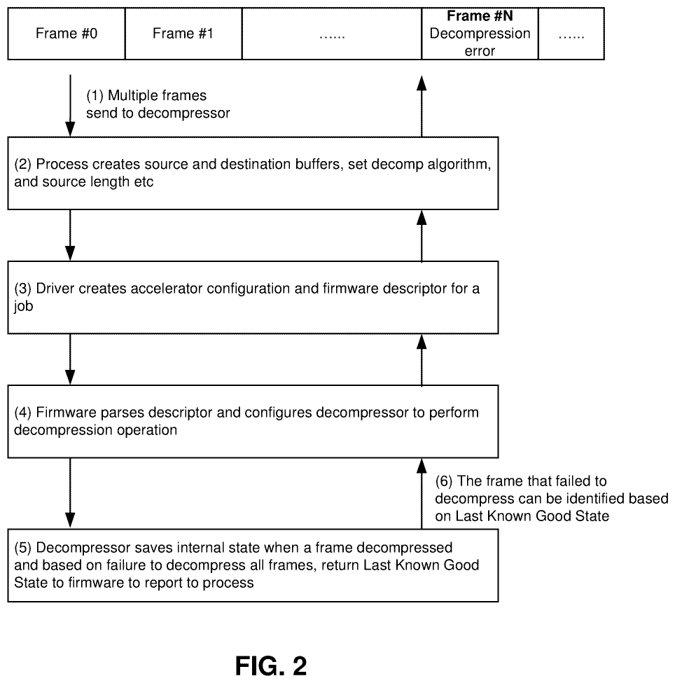

FIG. 2 depicts an example of operations. Compressed data in Frame #0 to #N (e.g., data 142) are stored sequentially in memory (e.g., memory 140). At (1), multiple compressed data frames are sent to decompressor to decompress in a single request or job. Decompressor supports multi-frame decompression based on Zstandard format, Snappy, LZ4, or other standards.

At (2), a process creates source and destination buffers, sets a source data length to be decompressed, and sets decompression algorithm to be applied. For example, request 120 can specify the source and destination buffers, sets a source data length to be decompressed, and set decompression algorithm.

At (3), a driver for a decompressor accelerator can configure the accelerator with a firmware descriptor for a job to decompress data of Frame #0 to #N. At (4), firmware for decompressor accelerator can parse the firmware descriptor and cause the decompressor to decompress data of Frame #0 to #N. At (5), the decompressor saves a state of the decompressed frames to identify progress towards completion of the data decompression job. Based on an occurrence of an error, decompressor internal states registers can be used to identify a frame in the compressed data to continue decompression operations. Various examples of decompressor internal state are described herein. At (6), the decompressor can report the state to the firmware to transfer to the process. Subsequently, the process can issue a second request to decompress one or more frames commencing at a frame that was not successfully decompressed. The process can provide a pointer to the frame in the source buffer that caused the decompression error based on LKGS and the process can allocate a different destination buffer in memory or to continue to use a prior destination buffer and store decompressed data after successfully decompressed data starting after the OBC indicated in LKGS.

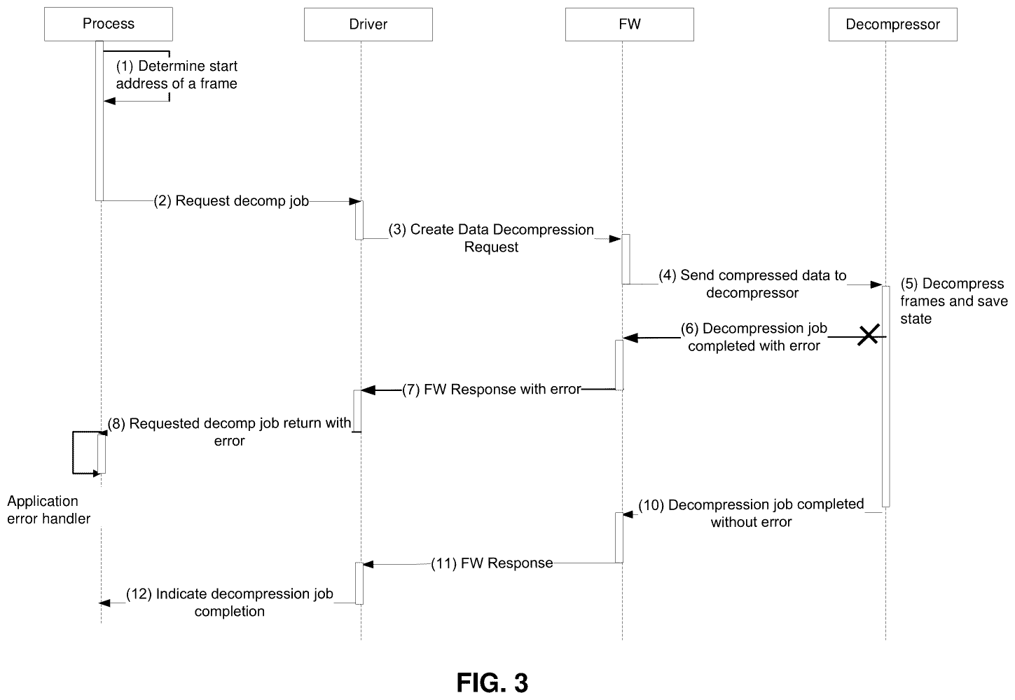

FIG. 3 depicts an example sequence. At (1), a process can determine a start address of a frame of data to read. At (2), the process can request a decompressor driver to perform a decompression (decomp) job of the frame of data. The request can specify a source (SRC) buffer address that identifies a start address of a first frame of the data and a data length of data to be decompressed. At (3), decompressor driver can issue a data decompression request to firmware of a decompressor. At (4), the firmware can cause compressed data to be sent to the decompressor after initialization of the decompressor. Initialization can include configuration of decompression hardware with a specific decompression algorithm, checksum type, whether checksum is present or not, or others. At (5), decompressor can decompress frames of data sequentially. When a frame is processed completely, the decompressor state (e.g., IBC, OBC, checksums) are saved to storage as the Last Known Good State.

However, at (6), when the decompression job encounters an error, the decompressor can report error to firmware. Decompressor can fail to decompress data at least because one of the frames failed to decompress. A reason for failing decompression can include overflow of the destination buffer, corrupted input data caused for example by memory errors or other failures, incomplete data due to software error, an unrecognized data format, unreadable input data, or other reasons. In the error state, decompressor returns Last Known Good State saved associated with a previously decompressed frame to a process that requested data decompression.

At (7), firmware creates a response based on the state of decompressor and provides the state to the decompressor driver. A firmware response can include IBC (e.g., length up to the end of previously decompressed frame), OBC (e.g., total length of cleartext decompressed up to the end of previously decompressed frame), and/or checksums (e.g., relative checksums of cleartext and compressed data up to the end of previously decompressed frame).

At (8), the driver can provide an indication, to the process, that the requested job did not complete and an error was encountered. For example, the indication can include: source (SRC) buffer address (e.g., start address of first frame of compressed data+IBC) and/or SRC data length (e.g., length of compressed data). The process error handler can process the indication and can return to (1) and submit another data decompression request based on SRC buffer address and SRC data length to request decompression of data starting at the frame that failed to decompress.

For a successful decompression of the data, at (10) the decompressor can indicate to firmware that a decompression completed without error. States of decompressor can be read by firmware. At (11), firmware can provide a response to the driver based on states of decompressor. The response can include IBC (e.g., total length of N input frames), OBC (e.g., total length of cleartext decompressed from N frames), and/or checksums (e.g., relative checksums of cleartext, compressed data etc.) At (12), the driver can indicate to the process that the decompression job completed.

While examples are described with respect to data decompression, examples can apply to data compression, data encryption, data decryption, or other operations.

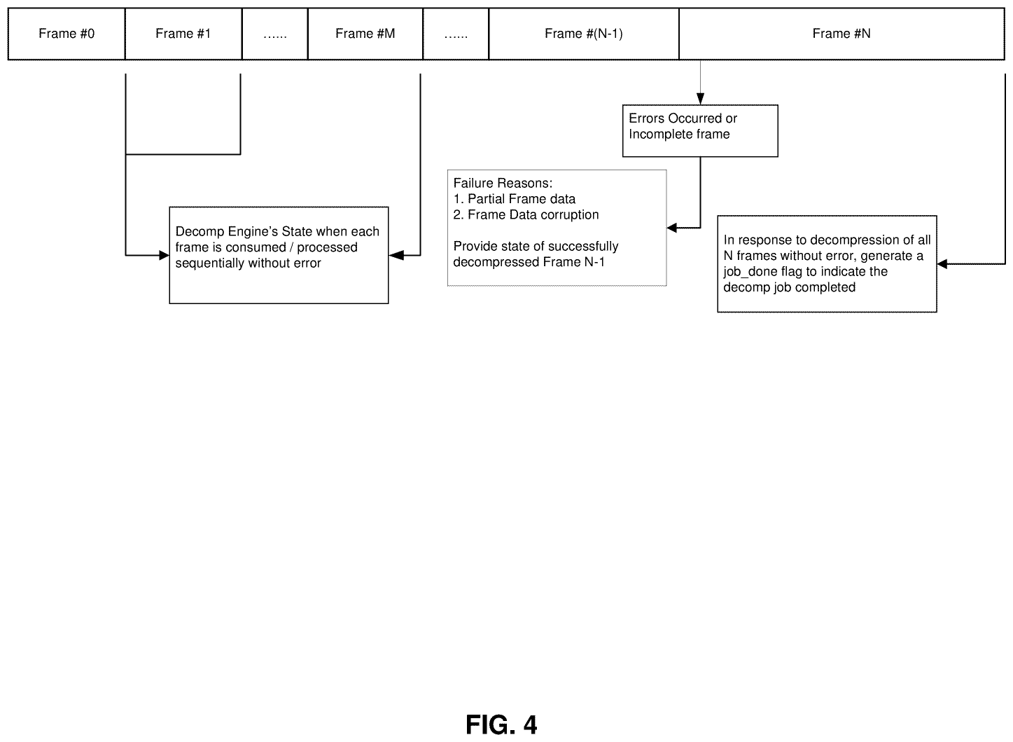

FIG. 4 depicts an example of state generation from decompressing multiple frames of data sequentially. In this example, decompressor successfully decompressed Frame #0. The decompressor can save decompression state (e.g., IBC, OBC, checksums, etc.) for the fully decompressed frame. The state of the decompressor when a frame is processed without error can include: IBC=sum (Length of Frame 1 to M); OBC=sum (Length of cleartext decompressed from Frame 1 to M); Input CRC or checksum=CRC or checksum (data in source buffer of length IBC); and Output CRC or checksum=CRC or checksum (cleartext data in destination buffer of length OBC).

If all N frames are decompressed without error, decompressor can generate a job_done flag to indicate the decompression job completed. However, in this example, Frame N fails to decompress. Failure reasons can include partial frame data or frame data corruption. Based on occurrence of an error, instead of providing the register state values (e.g., IBC, OBC, checksum), decompressor can provide the successfully processed frame's state (e.g., Last Known Good State of Frame N-1) to the process. For example, where the Frame N failed to decompress, the reported states can include: IBC (e.g., sum (Length of Frame 0 to N-1); OBC (e.g., sum (length of decompressed cleartext from Frame 0 to N-1); input CRC64 (e.g., CRC64 (IBC)); output CRC64 (e.g., CRC64 (OBC)); and XXHash64=XXHash64 (Frame N-1), where XXHash64 for a successfully decompressed frame may not be accumulated across frames.

For example, for decompression of Frame 0, the decompressor can store last known good state from decompressing Frame 0. For decompression of Frame 1, the decompressor can overwrite last known good state of Frame 0 and store last known good state from decompressing Frame 1. For decompression of Frame 2, the decompressor can overwrite last known good state of Frame 1 and store last known good state from decompressing Frame 2. Decompressor can attempt to decompress Frame 3 (e.g., Frame N). For failure to decompress Frame 3, the decompressor can share state of successfully decompressed Frame 2.

A process can resubmit a decompression job starting with Frame 2 last known good state with source pointing to input buffer that stores compressed data starting with Frame 3 and output points to output buffer that stores decompressed data. Last known good state of Frame 2 can impact decompression of Frame 3 because IBC of frames 0-2 (source buffer of compressed data) represents a start of Frame 3 in the source buffer and OBC of Frames 0-2 (destination buffer of decompressed data) represents a start of where to write decompressed Frame 3 (after storage of decompressed frames 0-2).

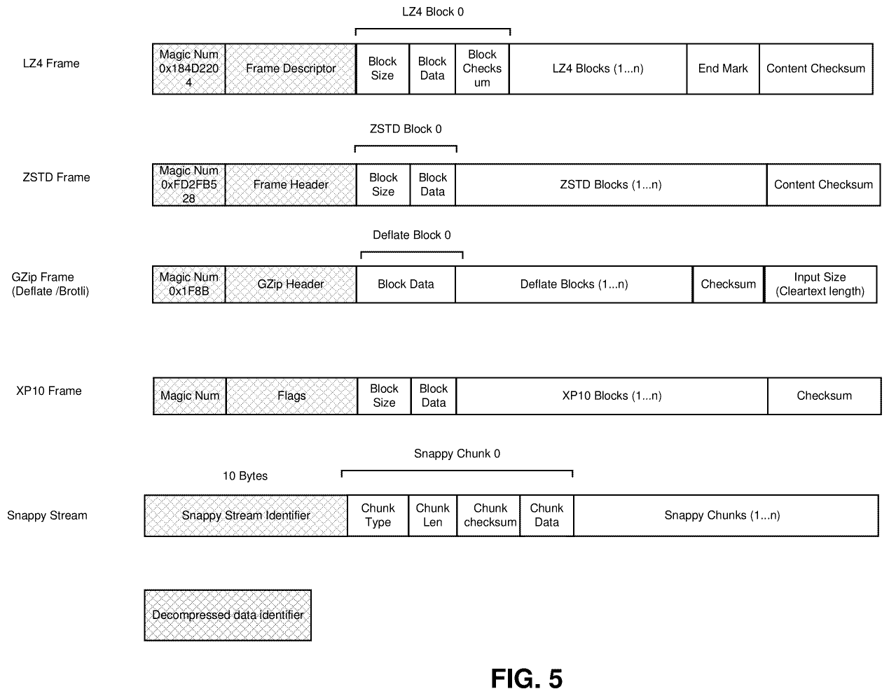

FIG. 5 shows an examples of frame formats. For example, LZ4, ZSTD, Gzip, XP10, and Snappy frame formats are depicted. An accelerator can decompress multiple frames of data. For example, an LZ4 frame can include a frame header that includes a 4 byte magic number (Magic Num) with value of 0x184D2204 and a frame descriptor having a length of 3-15 bytes. A frame descriptor can include a flag, a Block Dependency (BD) field, content size, dictionary ID, and an indicator of use of high compression (HC). For example, an LZ4 frame can include a frame footer that includes a 4 byte end mark and 0-4 byte content checksum.

For example, a ZSTD frame can include a 4 byte magic number (Magic Num) with a value of 0xFD2FB528 and a frame header having a length of 2-14 bytes. A frame header can include a 1 byte frame header descriptor, a 0-1 byte window descriptor, a 0-4 byte dictionary ID, and a 0-8 byte frame content size field. For example, a ZSTD frame can include a 32-bit checksum. A checksum can be a result of a xxh64 ( ) hash function digesting the decoded data as input and a seed of zero.

For example, a GZIP frame can include a frame header and a frame footer. A frame header can include a magic number (Magic Num) with a value of 0x1F8B. A frame footer can include a CRC-32 checksum and input size (e.g., a length of cleartext data).

For example, a Snappy stream can include a frame header. A frame header can be 4 bytes and indicate a length of the Snappy stream. The 4 byte header is not included in the length.

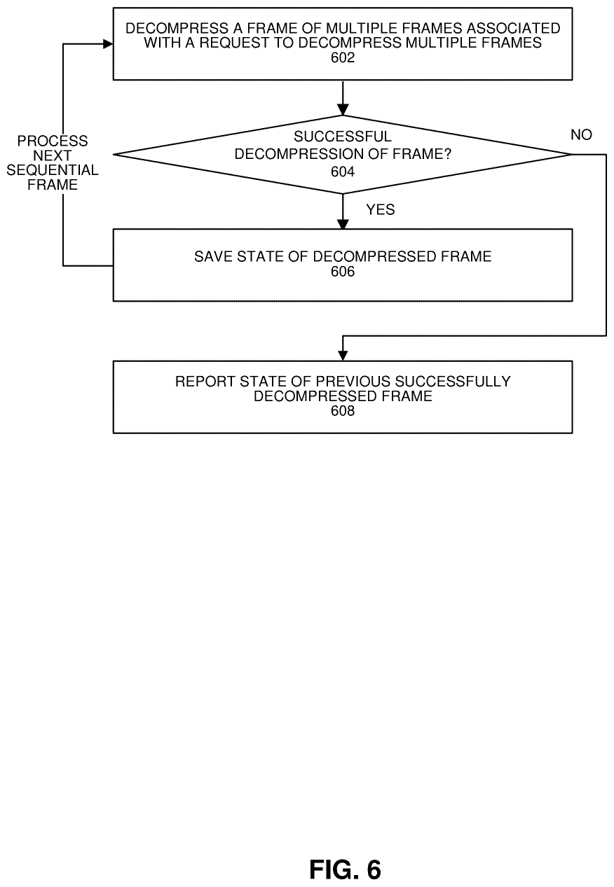

FIG. 6 depicts an example process. The process can be performed by an accelerator to perform offloaded decompression of data. At 602, decompression of a frame of a group of multiple frames can commence in frame sequence. At 604, a determination can be made as to whether a frame was successfully decompressed. At 606, based on successful decompression of the frame in 602, the process can proceed to save the state of the decompression operation. The state can include valid compressed data length (IBC), produced data (OBC), and one or more checksums. The process can proceed to 602 to decompress a next sequential frame in the group of multiple frames. At 608, based on unsuccessful decompression of the frame in 602, the process can report an error in decompression and indicate a state of the latest successfully decompressed frame. The state of the latest successfully decompressed frame can include at least IBC, OBC, and one or more checksums. Thereafter a process can submit a request to decompress the unsuccessfully decompressed frame and zero or more frames.

FIG. 7 depicts an example accelerator. Accelerator 700 can utilize compressor 702 to compress clear text data into a format specified by configuration circuitry 712 or perform data decompression 704 on data in a format specified by configuration circuitry 712 to clear text. Various examples of compression and decompression standards include at least Lempel Ziv (LZ) family of compression schemes including LZ77, LZ78, LZ4, Zstandard (ZSTD), DEFLATE, GZIP, XP10, and Snappy standards. To compress data, compressor 702 can store a dictionary into history buffer 710 to identify strings of characters to replace in data. Integrity value generator 714 can generate a security code on a dictionary, input data, and/or output data. A security code can include a cyclic redundancy check (CRC), hash calculation, or checksum. Accelerator 700 can utilize encryption 706 to encrypt cleartext or compressed data based on a specification in configuration 712. Accelerator 700 can utilize decryption 708 to decrypt data based on a specification in configuration 712. Configuration 712 can specify a standard of data encryption/decryption, including at least Triple Data Encryption Standard (3DES), Advanced Encryption Standard (AES), Digital Signature Algorithm (DSA), Rivest-Shamir-Adleman (RSA) algorithm, Elliptic Curve Digital Signature Algorithm (ECDSA), Elliptic Curve Cryptography (ECC), or others. Integrity value generator 714 can generate security codes (e.g., checksum, CRC values, or others) on cleartext or compressed data. Direct memory access (DMA) engines 716 can access data from memory (e.g., memory 140) and copy data into input buffer 718 based on a command from a process or copy data from output buffer 720 to memory (e.g., memory 140). Input buffer 718 can store data that is to be compressed, decompressed, encrypted, or decrypted. Output buffer 720 can store data that was compressed, decompressed, encrypted, or decrypted.

FIG. 8 depicts an example decompression circuitry. Buffer 802 can receive compressed data and provide one or more frames to frame header parser 804. Input integrity check 806 can generate an integrity check value (e.g., checksum, CRC, or others) on the compressed data. Frame header parser 804 can parse frames from buffer 802 and provide the frames for decompressing by decoder 808. Decoder 808 can decompress frames according to the decompression standard specified in a frame header and provide the decompressed data into fill buffer 810. History buffer 812 can receive the decompressed data from fill buffer 810 and output clear text to output buffer 814. Output integrity value generator 814 can generate an integrity check value (e.g., checksum, CRC, or others) on the decompressed data and provide the integrity check value to buffer 818.

Error logic 840 can indicate an error in decompressing a data frame by decoder 808. Based on an end of an uncompressed frame without error, at 822, state of the decompressor (e.g., IBC, OBC, checksums, or other values) can be saved into memory. However, if there is an error in decompressing a frame, at 820, the decompressor's LKGS can be stored into memory 830 instead of running state of decoder 808. State or LKGS can be provided with cleartext from buffer 818 and integrity values as output.

FIG. 9 depicts a system. The system can use examples to decompress data of multiple frames and report state of the last successfully decompressed frame, as described herein. In some examples, processor 910, graphics 940, one or more of accelerators 942, and/or network interface 950 can decompress data of multiple frames and report state of the last successfully decompressed frame, as described herein. System 900 includes processor 910, which provides processing, operation management, and execution of instructions for system 900. Processor 910 can include any type of microprocessor, central processing unit (CPU), graphics processing unit (GPU), processing core, or other processing hardware to provide processing for system 900, or a combination of processors. Processor 910 controls the overall operation of system 900, and can be or include, one or more programmable general-purpose or special-purpose microprocessors, digital signal processors (DSPs), programmable controllers, application specific integrated circuits (ASICs), programmable logic devices (PLDs), or the like, or a combination of such devices.

In one example, system 900 includes interface 912 coupled to processor 910, which can represent a higher speed interface or a high throughput interface for system components that needs higher bandwidth connections, such as memory subsystem 920 or graphics interface components 940, or accelerators 942. Interface 912 represents an interface circuit, which can be a standalone component or integrated onto a processor die.

Accelerators 942 can be a fixed function or programmable offload engine that can be accessed or used by a processor 910. For example, an accelerator among accelerators 942 can provide data compression (DC) capability, cryptography services such as public key encryption (PKE), cipher, hash/authentication capabilities, decryption, or other capabilities or services. In some cases, accelerators 942 can be integrated into a CPU socket (e.g., a connector to a motherboard or circuit board that includes a CPU and provides an electrical interface with the CPU). For example, accelerators 942 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 942 can provide multiple neural networks, CPUs, processor cores, general purpose graphics processing units, or graphics processing units can be made available for use by artificial intelligence (AI) or machine learning (ML) models. For example, the AI model can use or include one or more of: a reinforcement learning scheme, Q-learning scheme, deep-Q learning, or Asynchronous Advantage Actor-Critic (A3C), combinatorial neural network, recurrent combinatorial neural network, or other AI or ML model. Multiple neural networks, processor cores, or graphics processing units can be made available for use by AI or ML models.

Memory subsystem 920 represents the main memory of system 900 and provides storage for code to be executed by processor 910, or data values to be used in executing a routine. Memory subsystem 920 can include one or more memory devices 930 such as read-only memory (ROM), flash memory, one or more varieties of random access memory (RAM) such as static random-access memory (SRAM), dynamic random-access memory (DRAM), or other memory devices, or a combination of such devices. Memory 930 stores and hosts, among other things, operating system (OS) 932 to provide a software platform for execution of instructions in system 900. Additionally, applications 934 can execute on the software platform of OS 932 from memory 930. Applications 934 represent programs that have their own operational logic to perform execution of one or more functions. Processes 936 represent agents or routines that provide auxiliary functions to OS 932 or one or more applications 934 or a combination. OS 932, applications 934, and processes 936 provide software logic to provide functions for system 900. In one example, memory subsystem 920 includes memory controller 922, which is a memory controller to generate and issue commands to memory 930. It will be understood that memory controller 922 could be a physical part of processor 910 or a physical part of interface 912. For example, memory controller 922 can be an integrated memory controller, integrated onto a circuit with processor 910.

In some examples, OS 932 can be Linux®, Windows® Server or personal computer, FreeBSD®, Android®, MacOS®, iOS®, VMware vSphere, openSUSE, RHEL, CentOS, Debian, Ubuntu, or any other operating system. The OS and driver can execute on a CPU sold or designed by Intel®, ARM®, AMD®, Qualcomm®, IBM®, Texas Instruments®, among others.

In some examples, OS 932 or driver can advertise capability of at least one of accelerators 942 to decompress data of multiple frames and report state of the last successfully decompressed frame, as described herein. In some examples, OS 932 or driver can enable or disable use at least one of accelerators 942 to decompress data of multiple frames and report state of the last successfully decompressed frame.

While not specifically illustrated, it will be understood that system 900 can include one or more buses or bus systems between devices, such as a memory bus, a graphics bus, interface buses, or others. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a Peripheral Component Interconnect (PCI) bus, a Hyper Transport or industry standard architecture (ISA) bus, a small computer system interface (SCSI) bus, a universal serial bus (USB), or an Institute of Electrical and Electronics Engineers (IEEE) standard 1394 bus (Firewire).

In one example, system 900 includes interface 914, which can be coupled to interface 912. In one example, interface 914 represents an interface circuit, which can include standalone components and integrated circuitry. In one example, multiple user interface components or peripheral components, or both, couple to interface 914. Network interface 950 provides system 900 the ability to communicate with remote devices (e.g., servers or other computing devices) over one or more networks. In some examples, network interface 950 can refer to one or more of: a network interface controller (NIC), a remote direct memory access (RDMA)-enabled NIC, SmartNIC, router, switch, forwarding element, infrastructure processing unit (IPU), data processing unit (DPU), or network-attached appliance.

Network interface 950 can include an Ethernet adapter, wireless interconnection components, cellular network interconnection components, USB (universal serial bus), or other wired or wireless standards-based or proprietary interfaces. Network interface 950 can transmit data to a device that is in the same data center or rack or a remote device, which can include sending data stored in memory.

Some examples of network interface 950 are part of an Infrastructure Processing Unit (IPU) or data processing unit (DPU) or utilized by an IPU or DPU. An xPU can refer at least to an IPU, DPU, GPU, GPGPU, or other processing units (e.g., accelerator devices). An IPU or DPU can include a network interface with one or more programmable pipelines or fixed function processors to perform offload of operations that could have been performed by a CPU. The IPU or DPU can include one or more memory devices. In some examples, the IPU or DPU can perform virtual switch operations, manage storage transactions (e.g., compression, cryptography, virtualization), and manage operations performed on other IPUs, DPUs, servers, or devices.

Some examples of network interface 950 can include a programmable packet processing pipeline with one or multiple consecutive stages of match-action circuitry. The programmable packet processing pipeline can be programmed using one or more of: Protocol-independent Packet Processors (P4), Software for Open Networking in the Cloud (SONIC),

Broadcom® Network Programming Language (NPL), NVIDIA® CUDA®, NVIDIA® DOCATM, Data Plane Development Kit (DPDK), OpenDataPlane (ODP), Infrastructure Programmer Development Kit (IPDK), x86 compatible executable binaries or other executable binaries, or others.

In one example, system 900 includes one or more input/output (I/O) interface(s) 960. I/O interface 960 can include one or more interface components through which a user interacts with system 900 (e.g., audio, alphanumeric, tactile/touch, or other interfacing). Peripheral interface 970 can include any hardware interface not specifically mentioned above. Peripherals refer generally to devices that connect dependently to system 900. A dependent connection is one where system 900 provides the software platform or hardware platform or both on which operation executes, and with which a user interacts.

In one example, system 900 includes storage subsystem 980 to store data in a nonvolatile manner. In one example, in certain system implementations, at least certain components of storage 980 can overlap with components of memory subsystem 920. Storage subsystem 980 includes storage device(s) 984, which can be or include any conventional medium for storing large amounts of data in a nonvolatile manner, such as one or more magnetic, solid state, or optical based disks, or a combination. Storage 984 holds code or instructions and data 986 in a persistent state (e.g., the value is retained despite interruption of power to system 900). Storage 984 can be generically considered to be a “memory,” although memory 930 is typically the executing or operating memory to provide instructions to processor 910. Whereas storage 984 is nonvolatile, memory 930 can include volatile memory (e.g., the value or state of the data is indeterminate if power is interrupted to system 900). In one example, storage subsystem 980 includes controller 982 to interface with storage 984. In one example controller 982 is a physical part of interface 914 or processor 910 or can include circuits or logic in both processor 910 and interface 914.

A volatile memory is memory whose state (and therefore the data stored in it) is indeterminate if power is interrupted to the device. A non-volatile memory (NVM) device is a memory whose state is determinate even if power is interrupted to the device.

In an example, system 900 can be implemented using interconnected compute sleds of processors, memories, storages, network interfaces, and other components. High speed interconnects can be used such as: Ethernet (IEEE 802.3), remote direct memory access (RDMA), InfiniBand, Internet Wide Area RDMA Protocol (iWARP), Transmission Control Protocol (TCP), User Datagram Protocol (UDP), quick UDP Internet Connections (QUIC), RDMA over Converged Ethernet (RoCE), Peripheral Component Interconnect express (PCIe), Intel QuickPath Interconnect (QPI), Intel Ultra Path Interconnect (UPI), Intel On-Chip System Fabric (IOSF), Omni-Path, Compute Express Link (CXL), HyperTransport, high-speed fabric, NVLink, Advanced Microcontroller Bus Architecture (AMBA) interconnect, OpenCAPI, Gen-Z, Infinity Fabric (IF), Cache Coherent Interconnect for Accelerators (CCIX), 3GPP Long Term Evolution (LTE) (4G), 3GPP 5G, and variations thereof. Data can be copied or stored to virtualized storage nodes or accessed using a protocol such as NVMe over Fabrics (NVMe-oF) or NVMe.

Communications between devices can take place using a network, interconnect, or circuitry that provides chipset-to-chipset communications, die-to-die communications, packet-based communications, communications over a device interface (e.g., PCIe, CXL, UPI, or others), fabric-based communications, and so forth. A die-to-die communications can be consistent with Embedded Multi-Die Interconnect Bridge (EMIB).

Examples herein may be implemented in various types of computing and networking equipment, such as switches, routers, racks, and blade servers such as those employed in a data center and/or server farm environment. The servers used in data centers and server farms comprise arrayed server configurations such as rack-based servers or blade servers. These servers are interconnected in communication via various network provisions, such as partitioning sets of servers into Local Area Networks (LANs) with appropriate switching and routing facilities between the LANs to form a private Intranet. For example, cloud hosting facilities may typically employ large data centers with a multitude of servers. A blade comprises a separate computing platform that is configured to perform server-type functions, that is, a “server on a card.” Accordingly, a blade includes components common to conventional servers, including a main printed circuit board (main board) providing internal wiring (e.g., buses) for coupling appropriate integrated circuits (ICs) and other components mounted to the board.

Various examples may be implemented using hardware elements, software elements, or a combination of both. In some examples, hardware elements may include devices, components, processors, microprocessors, circuits, circuit elements (e.g., transistors, resistors, capacitors, inductors, and so forth), integrated circuits, ASICs, PLDs, DSPs, FPGAs, memory units, logic gates, registers, semiconductor device, chips, microchips, chip sets, and so forth. In some examples, software elements may include software components, programs, applications, computer programs, application programs, system programs, machine programs, operating system software, middleware, firmware, software modules, routines, subroutines, functions, methods, procedures, software interfaces, APIs, instruction sets, computing code, computer code, code segments, computer code segments, words, values, symbols, or any combination thereof. Determining whether an example is implemented using hardware elements and/or software elements may vary in accordance with any number of factors, such as desired computational rate, power levels, heat tolerances, processing cycle budget, input data rates, output data rates, memory resources, data bus speeds and other design or performance constraints, as desired for a given implementation. A processor can be one or more combination of a hardware state machine, digital control logic, central processing unit, or any hardware, firmware and/or software elements.

Some examples may be implemented using or as an article of manufacture or at least one computer-readable medium. A computer-readable medium may include a non-transitory storage medium to store logic. In some examples, the non-transitory storage medium may include one or more types of computer-readable storage media capable of storing electronic data, including volatile memory or non-volatile memory, removable or non-removable memory, erasable or non-erasable memory, writeable or re-writeable memory, and so forth. In some examples, the logic may include various software elements, such as software components, programs, applications, computer programs, application programs, system programs, machine programs, operating system software, middleware, firmware, software modules, routines, subroutines, functions, methods, procedures, software interfaces, API, instruction sets, computing code, computer code, code segments, computer code segments, words, values, symbols, or any combination thereof.

According to some examples, a computer-readable medium may include a non-transitory storage medium to store or maintain instructions that when executed by a machine, computing device or system, cause the machine, computing device or system to perform methods and/or operations in accordance with the described examples. The instructions may include any suitable type of code, such as source code, compiled code, interpreted code, executable code, static code, dynamic code, and the like. The instructions may be implemented according to a predefined computer language, manner, or syntax, for instructing a machine, computing device or system to perform a certain function. The instructions may be implemented using any suitable high-level, low-level, object-oriented, visual, compiled and/or interpreted programming language.

One or more aspects of at least one example may be implemented by representative instructions stored on at least one machine-readable medium which represents various logic within the processor, which when read by a machine, computing device or system causes the machine, computing device or system to fabricate logic to perform the techniques described herein. Such representations, known as “IP cores” may be stored on a tangible, machine readable medium and supplied to various customers or manufacturing facilities to load into the fabrication machines that actually make the logic or processor.

The appearances of the phrase “one example” or “an example” are not necessarily all referring to the same example or embodiment. Any aspect described herein can be combined with any other aspect or similar aspect described herein, regardless of whether the aspects are described with respect to the same figure or element. Division, omission, or inclusion of block functions depicted in the accompanying figures does not infer that the hardware components, circuits, software and/or elements for implementing these functions would necessarily be divided, omitted, or included in embodiments.

Some examples may be described using the expression “coupled” and “connected” along with their derivatives. For example, descriptions using the terms “connected” and/or “coupled” may indicate that two or more elements are in direct physical or electrical contact. The term “coupled,” however, may also mean that two or more elements are not in direct contact, but yet still co-operate or interact.

The terms “first,” “second,” and the like, herein do not denote any order, quantity, or importance, but rather are used to distinguish one element from another. The terms “a” and “an” herein do not denote a limitation of quantity, but rather denote the presence of at least one of the referenced items. The term “asserted” used herein with reference to a signal denote a state of the signal, in which the signal is active, and which can be achieved by applying any logic level either logic 0 or logic 1 to the signal (e.g., active-low or active-high). The terms “follow” or “after” can refer to immediately following or following after some other event or events. Other sequences of operations may also be performed according to alternative embodiments. Furthermore, additional operations may be added or removed depending on the particular applications. Any combination of changes can be used and one of ordinary skill in the art with the benefit of this disclosure would understand the many variations, modifications, and alternative embodiments thereof.

Disjunctive language such as the phrase “at least one of X, Y, or Z,” unless specifically stated otherwise, is otherwise understood within the context as used in general to present that an item, term, etc., may be either X, Y, or Z, or any combination thereof (e.g., X, Y, and/or Z). Thus, such disjunctive language is not generally intended to, and should not, imply that certain embodiments require at least one of X, at least one of Y, or at least one of Z to be present. Additionally, conjunctive language such as the phrase “at least one of X, Y, and Z,” unless specifically stated otherwise, should also be understood to mean X, Y, Z, or any combination thereof, including “X, Y, and/or Z.”′

Illustrative examples of the devices, systems, and methods disclosed herein are provided below. An embodiment of the devices, systems, and methods may include any one or more, and any combination of, the examples described below.
Example 1 includes one or more later examples and includes an apparatus that includes: an interface and circuitry to: perform offloaded decompression of multiple frames of data based on a data compression format, wherein the perform offloaded decompression of the multiple frames of data comprises: based on failure to decompress a frame of the multiple frames of the data: indicate, to a requester, device data identifying at least one of: a successfully decompressed frame of the multiple frames of data or an unsuccessfully decompressed frame.
Example 2 includes one or more earlier or later examples, wherein the circuitry is to: based on the device data, decompress the frame that failed to decompress and store the decompressed frame into a buffer with decompressed data of the multiple frames of data.
Example 3 includes one or more earlier or later examples, wherein the device data comprises one or more of: input compressed data byte count (IBC), output decompressed data byte count (OBC), integrity value of the IBC, or integrity value of the OBC.
Example 4 includes one or more earlier or later examples, wherein the circuitry is to: perform a received request to decompress the frame that failed to decompress to resume decompression of the multiple frames beginning at the frame that failed to decompress.
Example 5 includes one or more earlier or later examples, wherein the circuitry is to store at least one successfully decompressed frame of the multiple frames in a buffer.
Example 6 includes one or more earlier or later examples, wherein the circuitry comprises an accelerator and the accelerator is to perform one or more of: data compression, data encryption, or data decryption.
Example 7 includes one or more earlier or later examples, wherein the data compression format comprises one or more of: Zstandard, LZ77, LZ78, LZ4, DEFLATE, GZIP, XP10, or Snappy.
Example 8 includes one or more earlier or later examples, and includes at least one non-transitory computer-readable medium comprising instructions stored thereon, that if executed by one or more processors, cause the one or more processors to: configure an accelerator to: decompress data in multiple frames based on a data compression format and indicate, to a requester, a device data comprising a last successfully decompressed frame or unsuccessfully decompressed frame.
Example 9 includes one or more earlier or later examples, and includes instructions stored thereon, that if executed by one or more processors, cause the one or more processors to: configure the accelerator to: based on failure to decompress data in a frame of the multiple frames, decompress the frame that failed to decompress based on the device data.
Example 10 includes one or more earlier or later examples, and includes instructions stored thereon, that if executed by one or more processors, cause the one or more processors to: configure the accelerator to: store the decompressed frame into a buffer with decompressed data of the multiple frames of data.
Example 11 includes one or more earlier or later examples, wherein the device data comprises one or more of: input compressed data byte count (IBC), output decompressed data byte count (OBC), integrity value of data of length IBC, or integrity value of length OBC.
Example 12 includes one or more earlier or later examples, and includes instructions stored thereon, that if executed by one or more processors, cause the one or more processors to: configure the accelerator to: perform a received request to decompress the frame that failed to decompress to resume decompression of the multiple frames beginning at the frame that failed to decompress.
Example 13 includes one or more earlier or later examples, and includes instructions stored thereon, that if executed by one or more processors, cause the one or more processors to: configure the accelerator to store at least one successfully decompressed frame of the multiple frames into a buffer with decompressed data of the multiple frames of data.
Example 14 includes one or more earlier or later examples, wherein the accelerator is to perform one or more of: data compression, data encryption, or data decryption.
Example 15 includes one or more earlier or later examples, wherein the data compression format comprises one or more of: Zstandard, LZ77, LZ78, LZA, DEFLATE, GZIP, XP10, or Snappy.
Example 16 includes one or more earlier or later examples, and includes a method that includes: performing, by an accelerator, an offloaded operation of decompressing multiple frames of data by: decompressing data in the multiple frames based on a data compression standard and based on failure to decompress data in a frame of the multiple frames, indicating, to a requester, a device data comprising a last successfully decompressed frame or unsuccessfully decompressed frame.
Example 17 includes one or more earlier or later examples, wherein the device data comprises one or more of: input compressed data byte count (IBC), output decompressed data byte count (OBC), integrity value of the IBC, or integrity value of the OBC.
Example 18 includes one or more earlier or later examples, and includes the accelerator performing a request to decompress the frame that failed to decompress.
Example 19 includes one or more earlier or later examples, and includes the accelerator performing: storing at least one successfully decompressed frame of the multiple frames in a buffer for access by a process that requested data decompression.
Example 20 includes one or more earlier or later examples, wherein the data compression standard comprises one or more of: Zstandard, LZ77, LZ78, LZA, DEFLATE, GZIP, XP10, or Snappy.

1. An apparatus comprising:
an interface and
circuitry to:
perform offloaded decompression of multiple frames of data based on a data compression format, wherein the perform offloaded decompression of the multiple frames of data comprises:
based on failure to decompress a frame of the multiple frames of the data: indicate, to a requester, device data identifying at least one of: a successfully decompressed frame of the multiple frames of data or an unsuccessfully decompressed frame.

2. The apparatus of claim 1, wherein the circuitry is to:
based on the device data, decompress the frame that failed to decompress and store the decompressed frame into a buffer with decompressed data of the multiple frames of data.

3. The apparatus of claim 1, wherein the device data comprises one or more of: input compressed data byte count (IBC), output decompressed data byte count (OBC), integrity value of data of length IBC, or integrity value of length OBC.

4. The apparatus of claim 1, wherein the circuitry is to:
perform a received request to decompress the frame that failed to decompress to resume decompression of the multiple frames beginning at the frame that failed to decompress.

5. The apparatus of claim 1, wherein the circuitry is to store at least one successfully decompressed frame of the multiple frames in a buffer.

6. The apparatus of claim 1, wherein the circuitry comprises an accelerator and the accelerator is to perform one or more of: data compression, data encryption, or data decryption.

7. The apparatus of claim 1, wherein the data compression format comprises one or more of:
Zstandard, LZ77, LZ78, LZA, DEFLATE, GZIP, XP10, or Snappy.

8. At least one non-transitory computer-readable medium comprising instructions stored thereon, that if executed by one or more processors, cause the one or more processors to:
configure an accelerator to:
decompress data in multiple frames based on a data compression format and indicate, to a requester, a device data comprising a last successfully decompressed frame or unsuccessfully decompressed frame.

9. The non-transitory computer-readable medium of claim 8, comprising instructions stored thereon, that if executed by one or more processors, cause the one or more processors to:
configure the accelerator to:
based on failure to decompress data in a frame of the multiple frames, decompress the frame that failed to decompress based on the device data.

10. The non-transitory computer-readable medium of claim 9, comprising instructions stored thereon, that if executed by one or more processors, cause the one or more processors to:
configure the accelerator to:
store the decompressed frame into a buffer with decompressed data of the multiple frames of data.

11. The non-transitory computer-readable medium of claim 8, wherein the device data comprises one or more of: input compressed data byte count (IBC), output decompressed data byte count (OBC), integrity value of data of length IBC, or integrity value of length OBC.

12. The non-transitory computer-readable medium of claim 8, comprising instructions stored thereon, that if executed by one or more processors, cause the one or more processors to:
configure the accelerator to:
perform a received request to decompress the frame that failed to decompress to resume decompression of the multiple frames beginning at the frame that failed to decompress.

13. The non-transitory computer-readable medium of claim 12, comprising instructions stored thereon, that if executed by one or more processors, cause the one or more processors to:
configure the accelerator to store at least one successfully decompressed frame of the multiple frames into a buffer with decompressed data of the multiple frames of data.

14. The non-transitory computer-readable medium of claim 8, wherein the accelerator is to perform one or more of: data compression, data encryption, or data decryption.

15. The non-transitory computer-readable medium of claim 8, wherein the data compression format comprises one or more of: Zstandard, LZ77, LZ78, LZ4, DEFLATE, GZIP, XP10, or Snappy.

16. A method comprising:
performing, by an accelerator, an offloaded operation of decompressing multiple frames of data by:
decompressing data in the multiple frames based on a data compression standard and
based on failure to decompress data in a frame of the multiple frames, indicating, to a requester, a device data comprising a last successfully decompressed frame or unsuccessfully decompressed frame.

17. The method of claim 16, wherein the device data comprises one or more of: input compressed data byte count (IBC), output decompressed data byte count (OBC), integrity value of data of length IBC, or integrity value of length OBC.

18. The method of claim 16, comprising:
the accelerator performing a request to decompress the frame that failed to decompress.

19. The method of claim 16, comprising:
the accelerator performing: storing at least one successfully decompressed frame of the multiple frames in a buffer for access by a process that requested data decompression.

20. The method of claim 16, wherein the data compression standard comprises one or more of:
Zstandard, LZ77. LZ78. LZ4, DEFLATE, GZIP. XP10, or Snappy.
